(19) United States
(12) Patent Application Publication
(10) Pub. No.: US 2009/0273053 A1
(43) Pub. Date: Nov. 5, 2009

(54) SEMICONDUCTOR DEVICE INCLUDING ANALOG CIRCUITRY HAVING A PLURALITY OF DEVICES OF REDUCED MISMATCH

(76) Inventors: Matthias Baer, Hohenstein-Ernstthal (DE); Sreenivasa Chalamala, Dresden (DE); Karl-Heinz Sandig, Dresden (DE)

Correspondence Address: WILLIAMS, MORGAN & AMERSON, 10333 RICHMOND, SUITE 1100, HOUSTON, TX, 77042, US

(21) Appl. No.: 12/367,106

(22) Filed: Feb. 6, 2009

(30) Foreign Application Priority Data
Apr. 30, 2008 (DE) 10 2008 021 564.3

(51) Int. Cl. H01L 27/04; H01R 43/00

(52) U.S. Cl. 257/528; 29/825; 257/E27.01

(57) ABSTRACT

In an analog circuit portion, a systematic mismatch between a plurality of circuit elements may be reduced in view of a technology gradient by appropriately positioning the unit devices of the circuit elements so as to obtain a similar response of the circuit elements with respect to the gradient. For example, the spatial relationship of adjacent unit devices belonging to the same circuit element along an arbitrary lateral direction may be the same as the spatial relationship of adjacent unit devices of another circuit element.

### BACKGROUND

1. Field of the Disclosure

Generally, the present disclosure relates to integrated circuits and methods for forming the same in which the operational behavior of the integrated circuits, and in particular of analog circuitry portions, may be enhanced by reducing the effects of mismatch of circuit elements, such as transistors, capacitors, resistors and the like, in view of systematic deviations, also referred to as gradients, which may be introduced during the fabrication and/or operation of the integrated circuits.

2. Description of the Related Art

In the fabrication of modern integrated circuits, there is a continuous drive to steadily reduce the feature sizes of the circuit elements, thereby enhancing the functionality of these structures. For instance, in currently available integrated circuits, minimum feature sizes, such as the channel length of field effect transistors, have reached the deep sub-micron range, thereby increasing performance of these circuits in terms of speed and/or power consumption. In the overall process for forming integrated circuit devices from an appropriate raw material, which currently is, and will remain in the near future, silicon-based semiconductor materials, due to the superior availability of the raw material and the well-understood characteristics of silicon, silicon dioxide and other well-approved materials, a great number of highly complex fabrication processes have to be performed, wherein each of these processes may have to be carried out on the basis of tightly set process windows in order to obtain the desired process result. For example, the substrate material, for instance in the form of silicon-based semiconductor wafers, may be treated by using photolithography, etch techniques, ion implantation, anneal processes, deposition processes and the like, in order to produce the various microstructure features which may finally form the individual circuit elements which may commonly define the functional behavior of the designed circuit layout. Currently, a plurality of process technologies are practiced in order to accommodate the various requirements of specific circuit designs, wherein, however, the above-described process techniques may be used in a more or less modified version in any of these technologies, wherein, however, the requirements with respect to high precision, in combination with a cost-effective overall manufacturing flow, may have to be met in any of these technologies in order to guarantee commercial success of the finally obtained semiconductor product. As an example of a highly complex manufacturing sequence, a typical process flow for forming circuit elements in MOS technology may be described with reference to FIGS. 1a and 1b.

FIG. 1a schematically illustrates a top view of a portion of an integrated circuit 100 which may comprise analog circuitry, such as voltage and current amplifiers, which may be used in signal processing for analog circuit portions, such as ADCs (analog-to-digital converters), DACs (digital-to-analog converters) and the like. It should be appreciated that, although a significant tendency may be observed towards digital circuitry in many technical fields, for instance on the basis of digital signal processing, nevertheless highly accurate analog circuitry may be required, even in combination with complex digital circuits, since the analog circuit may at least act as an interface between the physical analog signals at the input side and output side of any digital signal processing system. That is, as the degree of control functions and signal processing capability may be enhanced in a plurality of technical fields, which may have previously been dedicated to pure analog circuitry, also the analog interface circuitry may have to meet restrictive requirements with respect to accuracy, since performance of the digital portion of the circuitry is substantially determined by the signal processing capability of the analog interface, thereby also requiring an increased degree of accuracy of the analog circuit portions, while, on the other hand, additional requirements may have to be respected, for instance in terms of reduced power consumption and high packing density, which may partially be in contradiction with the requirement of enhanced accuracy, as will be explained later on in more detail.

The integrated circuit 100 may, in the example shown, be represented by a circuit element in the form of a transistor, in the case of MOS technology, an N-channel field effect transistor or a P-channel field effect transistor. The transistor 100 may thus comprise a substrate 101 which may be provided in the form of any appropriate base material, such as a substantially crystalline silicon material, as the vast majority of complex integrated circuits may be formed of silicon due to the advantages mentioned above. The substrate 101 may have formed thereabove a semiconductor layer (not shown), such as a silicon layer, portions of which may be appropriately treated to receive a dopant species for modifying the overall electronic characteristics in order to obtain drain and source regions 103 of the transistor 100. It should be appreciated that a plurality of device architectures may be used, such as silicon-on-insulator (SOI) architecture in which a buried insulating layer (not shown) may be positioned between the substrate material 101 and the semiconductor layer. In other cases, the semiconductor layer may represent an upper portion of the substantially crystalline substrate material 101 so that the drain and source regions 103 may have contact to deeper lying substrate areas, which may be referred to as a bulk configuration. Furthermore, the transistor 100 comprises a gate electrode structure 104 which may include a gate electrode, i.e., a conductive portion, possibly in combination with insulating sidewall spacer elements, as will be described later on with reference to FIG. 1b. The dimension of the transistor 100 may be substantially defined by an isolation structure 102, which may be provided in the form of any appropriate insulating material, such as silicon dioxide, silicon nitride and the like, wherein the isolation region 102 may have any appropriate configuration, such as a shallow trench isolation, a field oxide and the like. Furthermore, as indicated in FIG. 1a, a length direction, indicated as L, may represent the direction of current flow in the transistor 100, while a width direction, indicated as W, may represent a direction that is substantially perpendicular to the current flow during operation of the transistor 100.

FIG. 1b schematically illustrates a cross-sectional view of the transistor 100 as shown in FIG. 1a. Thus, the transistor 100 comprises the drain and source regions 103 defined by a corresponding vertical and lateral dopant profile with an intermediate channel region 105, the length of which is determined by PN junctions of the drain and source regions 103. The channel length CL is correlated with a length GL of a gate electrode 104A, which represents a conductive portion of the gate electrode structure 104. The gate electrode 104A is separated from the channel region 105 by a gate dielectric material 104B, which may be comprised of well-established dielectric materials, such as silicon dioxide, silicon nitride, silicon oxynitride and the like, while, in highly advanced semiconductor devices, other dielectric materials, such as so-called high-k dielectric materials, may be used. A high-k dielectric material is to be understood as a dielectric material having a dielectric constant of 10 or higher. The material composition and the thickness of the gate dielectric material 104B may have a significant influence on the overall performance of the transistor 100 as a capacitive coupling of the gate electrode 104A to the channel region 105 may control the overall conductivity, in combination with the overall dopant concentration in the drain and source regions 103 and the channel region 105, when building up a conductive channel upon application of an appropriate control voltage to the gate electrode 104A. Furthermore, the control mechanism, as well as the conductivity per unit length, may also depend on the channel length CL and thus the gate length GL so that the general electrical behavior of the transistor 100 may be significantly determined by the threshold voltage of the transistor 100, i.e., the gate-source voltage at which a conductive channel starts to build up in the channel region 105 and which may be substantially determined by the dopant profile in the channel region 105 and the coupling characteristics of the gate electrode 104A and the channel region 105 via the gate dielectric material 104B. Furthermore, the channel length CL may also have a significant effect on the overall transistor characteristics.

Furthermore, depending on the overall process strategy and the device requirements, the gate electrode structure 104 may comprise a sidewall spacer structure 104C, which may be appropriately designed for adjusting the lateral dopant profile in the drain and source regions 103 formed in the semiconductor layer 106. As previously indicated, in sophisticated integrated circuits, the minimum feature sizes, such as the gate length GL, may be in the deep sub-micron range, thereby requiring sophisticated manufacturing processes in order to obtain electrical characteristics of the device 100 as specified during the design phase of the device 100.

Typically, the manufacturing process for forming the transistor 100 as shown in FIGS. 1a and 1b may include the following processes. After providing the substrate 101 having formed thereabove the semiconductor layer 106, which may include a certain degree of basic dopant concentration, respective die regions, i.e., functional entities including a large number of circuit elements such as the transistor 100, which may be separated after completing the basic circuit configuration and prior to packaging the individual die regions, may be defined on the basis of design rules. That is, the substrate 101 may comprise a large number of die regions, for instance several hundred die regions, depending on the overall size of the substrate 101 and the integrated circuit under consideration. For this purpose, sophisticated lithography processes may be performed, for instance for providing an etch mask, which may define a plurality of “active” regions in the semiconductor layer 106 in and above which respective circuit components such as the transistor 100 may be formed. Thereafter, appropriately dimensioned trenches may be etched into the semiconductor layer 106 and may subsequently be filled with an appropriate insulating material, such as silicon dioxide, silicon nitride and the like. Next, excess material may be removed and the resulting surface topography may be planarized, for instance by etch processes, chemical mechanical polishing (CMP) and the like, in order to prepare the surface for subsequent deposition steps, for instance for providing a dielectric material for the layer 104B and a gate electrode material. Next, sophisticated lithography and etch techniques may be performed in order to pattern the gate electrode 104A and the gate insulation layer 104B, thereby significantly determining the finally obtained characteristics of the transistor 100, as previously indicated. The gate electrode 104A, in combination with appropriate sidewall spacer elements (not shown), may be used for a subsequent implantation sequence for establishing the complex dopant profile in the semiconductor layer 106 bordered by the isolation structure 102, wherein, as previously explained, prior to forming the gate electrode 104A, appropriate implantation processes may have been performed in order to adjust the dopant concentration in the channel region 105, which may have a significant influence on the finally obtained threshold voltage of the transistor 100. Thereafter, the spacer structure 104C may be formed in a more or less complex configuration wherein, depending on the lateral profile of the drain and source regions 103, intermediate implantation processes may be performed in order to adjust the overall conductivity of the drain and source regions 103 and also determine the control characteristics of the channel region 105, which may require complex implantation processes for devices having a channel length CL of 100 nm and less. Thereafter, the further processing may be continued by performing anneal processes for activating the previously implanted dopant species and also to re-crystallize implantation-induced damage, wherein a certain degree of dopant diffusion may also take place, thereby adjusting the final effective channel length CL since the dopant species in the drain and source regions 103 may be driven into the channel region 105 and, inversely, dopant species in the channel region 105 may be driven into the drain and source regions 103. Thereafter, if required, the overall conductivity of the drain and source regions 103 and the gate electrode 104A may be increased by forming a metal-containing material therein and an interlayer dielectric material may be deposited for enclosing and passivating the circuit elements. Next, a contact structure may be formed within the interlayer dielectric material and typically a plurality of metallization levels may be formed to establish the electrical connection of the individual circuit elements in accordance with the overall circuit layout. Also, these additional process steps performed after completing the basic transistor structure, as shown in FIG. 1b, may include a plurality of very complex manufacturing processes. Consequently, the finally obtained electrical characteristics of the transistor 100 may depend on a plurality of process steps, each of which is typically associated with a certain degree of variation, which may finally result in a certain spread of the electrical behavior of the circuit elements which may have to be taken into consideration when designing the basic circuit layout so as to obtain the desired functionality in view of unavoidable manufacturing tolerances. For example, electrical parameters, such as the threshold voltage of the transistor 100, the transconductance thereof and the like, may significantly depend on the overall transistor dimensions and the respective dopant profiles, which in turn may be determined by a plurality of highly complex manufacturing processes, each of which may include a certain degree of variability, wherein the variability may be encountered between individual substrates, within individual substrates and even within individual die regions so that, even for the same basic configuration, the characteristics of the transistor 100, when provided at different die regions, may result in different electrical characteristics.

As an example, a plurality of the highly complex manufacturing processes may be sensitive with respect to pattern density, such as etch processes, deposition processes and the like, wherein a different number of circuit elements per unit area may result in a different process output, thereby creating a die-internal mismatch of device characteristics. That is, a mismatch may be understood as a deviation of an electrical characteristic with respect to a reference or design characteristic, which may be caused by a plurality of influences, such as variations in the manufacturing processes and the like. Hence, for two devices formed on the basis of the same design criteria, a mismatch may be defined by the difference or ratio of the electrical characteristic under consideration. A corresponding mismatch may be measured by, for instance, forming a plurality of “identical” circuit elements and measuring the respective electrical characteristic. From the measurement values, a mean value of the mismatch and a standard deviation may be determined, thereby obtaining a systematic mismatch, i.e., the mean value of the mismatch and a random mismatch indicated by the standard deviation. Hence, the corresponding values, i.e., the systematic and the random mismatch, may be representative for the technology under consideration for a specified type of circuit elements, such as transistors. The random mismatches are typically due to process variations, as previously described, and represent statistical variations of process fluctuations, for instance the scattering of dopant atoms, i.e., the distribution of the dopants in the drain and source regions 103 and the channel region 105. Thus, for a given technology standard, the random mismatches may not be eliminated but may be reduced, for instance by increasing the overall device dimensions, as typically the random mismatch may be proportional to the inverse of the square of the active area of the circuit element under consideration. For instance, with respect to the transistor element 100, the random mismatch between two “identical” transistor elements may be reduced by increasing the transistor width and the transistor length so that an increase of a factor 4 in the active transistor area may reduce the overall random mismatches by a factor of 2. However, arbitrarily increasing the size of the circuit elements under consideration may be in contradiction with other design goals, such as reduced power consumption and high packing density, as typically increased transistor size is associated with increased power consumption and reduced speed while also the overall packing density may be reduced.

In addition to the random mismatches, systematic mismatches may also have a significant effect on the overall device behavior, wherein a systematic mismatch may be induced by, for instance, a spatially dependant non-uniformity during the operation and/or processing of the integrated circuit. For instance, one example of a systematic mismatch may be caused by a temperature gradient, wherein two circuit elements of basically the same design may experience a different temperature due to the temperature gradient, thereby creating a systematic deviation in the electrical characteristics. Other spatially dependant influences represent “stationary” effects which may be caused during the overall manufacturing sequence and may thus be dependent on the technology under consideration. For example, as previously indicated, a plurality of processes may depend on pattern density, thereby introducing a systematic variation of respective process results so that a corresponding “gradient” with respect to a process result, such as a layer thickness, dopant concentration and the like, may be induced. Furthermore, more “global” gradients may be introduced, for instance, since many processes may have certain non-uniformity across the entire substrate, for instance when a process may lead to different process results at the substrate center compared to the substrate edge and the like.

Consequently, when designing a sophisticated analog circuit portion, device mismatch may have to be taken into consideration and may have to be balanced against power consumption and accuracy as well as device speed in order to obtain the desired overall performance of the circuit under consideration. However, in many analog circuit portions, a mismatch between individual circuit elements, such as transistors, capacitors, resistors and the like, may have to be reduced as much as possible in order to obtain a required degree of accuracy.

FIG. 1c schematically illustrates an example of a basic differential voltage amplification stage 110, which may comprise transistors 100A, 100B which may have substantially the same configuration as described with reference to the transistor 100. The amplification stage 110 may further comprise resistors 111 and 112 connected to the input and output so as to provide a feedback, while constant current sources 113 and 114 may also be provided, for instance in the form of transistors and the like. Hence, the overall electrical performance of the amplifier stage 110 may significantly depend on the degree of matching of the transistors 110A, 110B, wherein a certain degree of random mismatch may be inevitable due to the overall design criteria. That is, for a selected design size of the transistors 100A, 100B and the technology standard under consideration, a random mismatch exists, as previously explained. Furthermore, as described above, an additional systematic mismatch may occur, indicated as a gradient 115, which may, for instance, be induced by the technology under consideration. For example, due to a spatial dependency of a deposition process and/or an oxidation process, the gate insulation layer of the transistors 100A, 100B may be different due to the gradient 115, thereby resulting in a systematic mismatch which, in principle, could be taken into consideration if a corresponding gradient 115 would be known in advance. However, the magnitude and also the direction of the gradient 115 may vary and may therefore be non-predictable. For this reason, a plurality of layout criteria may be used to reduce the mismatch between respective two circuit elements, such as the transistors 100A, 100B.

FIG. 1e schematically illustrates a schematic top view of the circuit 110 wherein only the transistors 100A, 100B are illustrated. As previously explained, random mismatches may be reduced by increasing the overall dimensions of the transistors, wherein typically the final desired size of a circuit element, such as a transistor, may be defined on the basis of a plurality of unit devices, i.e., devices formed on the basis of minimum critical dimensions corresponding to the technology standard under consideration, which may have identical design characteristics and are appropriately combined in a required number in order to obtain the desired final dimensions and electrical characteristics. In the example shown in FIG. 1e, it may be assumed that the transistors 100A, 100B may both be comprised of two unit devices of identical design which, however, as previously explained, may exhibit a certain degree of mismatch wherein the unit devices A, B, C, D may be appropriately combined to reduce random and systematic mismatches. A well-established principle for matching two circuit elements is to define a centroid of the unit devices for each circuit element and try to position the unit devices such that the respective centroids may substantially coincide with each other. For example, in the arrangement shown in FIG. 1e, the transistor 100A may be formed by the unit devices A and D, thereby defining the centroid 111 while the transistor 100B may be formed by the unit devices B and C, thereby also defining the centroid 111. Thus, a substantially inter-digitizing configuration may be obtained wherein both centroids of the transistors 100A, 100B may coincide.

FIG. 1d schematically illustrates another example in which capacitors may be formed on the basis of capacitive unit devices having a substantially square shape, wherein, in addition to a reduction of mismatches, also a ratio of 1:5 of the respective capacitance values may be adjusted. For example, a capacitor 100D may be defined by two unit devices D, thereby defining the centroid 111, as indicated in FIG. 1d. Furthermore, a capacitor 100E may be defined by unit devices E, surrounding the capacitor 100D, thereby also defining the centroid 111 so that both capacitors 100D, 100E have coinciding centroids.

Thus, the above-specified layout criteria may significantly reduce the degree of mismatch for respective two circuit elements, however a reduction of systematic mismatches, such as technology-induced gradients for a plurality of circuit elements, that is, three or more circuit elements or an array of circuit elements, may be difficult to be achieved on the basis of conventional strategies.

The present disclosure is directed to various methods and devices that may avoid, or at least reduce, the effects of one or more of the problems identified above.

### SUMMARY OF THE DISCLOSURE

The following presents a simplified summary of the disclosure in order to provide a basic understanding of some aspects disclosed herein. This summary is not an exhaustive overview, and it is not intended to identify key or critical elements of the invention or to delineate the scope of the invention. Its sole purpose is to present some concepts in a simplified form as a prelude to the more detailed description that is discussed later.

Generally, the subject matter disclosed herein provides integrated circuits and methods for forming the same in which systematic mismatch between a plurality of individual circuit elements, such as transistors, capacitors, resistors and the like, may be reduced by appropriately positioning the unit devices of each of the plurality of circuit elements according to a spatial relationship, which provides highly similar effects of a technology gradient on each of the plurality of individual circuit elements, irrespective of the direction of the gradient. That is, the plurality of unit devices for each of the individual circuit elements may be arranged so as to exhibit the same spatial relationship according to an arbitrarily selected direction so that a respective technology gradient, that induces a systematic variation of a characteristic, may hence affect each circuit element in substantially the same manner. Consequently, the matching of a plurality of circuit elements, in particular in analog circuitry portions, may be enhanced since systematic variations induced by the overall manufacturing flow may be compensated for or at least significantly reduced, while other gradient effects, such as temperature-related effects and the like, may have a reduced effect on the matching of the plurality of circuit elements, thereby possibly providing an increased degree of flexibility for the design of the circuitry since, for instance, temperature-related gradients may be acceptable without having a significant influence on the overall accuracy of the circuit portion under consideration, which may allow positioning more circuit elements more closely to temperature-critical device areas, as may be the case in sophisticated integrated circuits including control circuitry, power circuitry and the like. Moreover, due to the increased robustness against technology-induced gradients, increased production yield may be obtained, even for process technologies which may require frequent upgrading of processes which may conventionally introduce process-induced gradients.

One illustrative integrated circuit disclosed herein comprises three or more circuit elements, each of which is comprised of a plurality of substantially identical unit devices. Each unit device belonging to a respective one of the three or more circuit elements has, with respect to a first direction, a first substantially constant distance to a nearest neighboring one of the unit devices belonging to the respective one of the three or more circuit elements. Furthermore, each unit device belonging to the respective one of the three or more circuit elements has, with respect to a second direction, a second substantially constant distance to a nearest neighboring of one of the unit devices belonging to the respective one of the three or more circuit elements.

A further illustrative integrated circuit disclosed herein comprises an analog circuit portion and a plurality of more than two circuit elements provided in the analog circuit portion. Each of the plurality of circuit elements is comprised of a plurality of unit devices of substantially the same configuration, wherein, for each of the plurality of circuit elements, a spatial relationship of unit devices along a lateral direction is substantially identical.

One illustrative method disclosed herein comprises defining a plurality of unit devices which have the same design and which define a plurality of circuit elements of an integrated circuit. The method further comprises determining design positions of the plurality of unit devices so as to obtain the same spatial relationship of unit devices along an arbitrary lateral direction for each of the plurality of circuit elements. Additionally, the method comprises forming the plurality of circuit elements above a substrate using the design positions for the plurality of unit devices.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate a top view and a cross-sectional view, respectively, of an analog circuit portion including a transistor element formed in accordance with well-established process techniques;

FIG. 1c schematically illustrates a circuit diagram of a basic voltage amplification stage with matched transistors;

FIG. 1d schematically illustrates a plurality of unit devices of a capacitive structure arranged according to conventional layout strategies for reducing the mismatch;

FIG. 1e schematically illustrates a top view of a plurality of unit devices for forming the matched transistors of FIG. 1c according to conventional strategies;

FIG. 2a schematically illustrates a top view of circuit elements formed on the basis of a plurality of unit devices arranged in an appropriate spatial relationship to each other so that the circuit elements may be attacked in substantially the same manner by a technology gradient, according to illustrative embodiments;

FIGS. 2b-2d schematically illustrate top views of semiconductor devices formed in accordance with the arrangement shown in FIG. 2a, according to further illustrative embodiments;

FIG. 2e schematically illustrates an array of circuit elements formed by a plurality of unit devices arranged so as to reduce a systematic mismatch caused by a gradient, according to still further illustrative embodiments;

FIGS. 2f-2g schematically illustrate top views of circuit elements formed on the basis of unit devices, while different sizes of the circuit element may be provided on the basis of a spatial arrangement of the unit devices for reducing systematic mismatches, according to still further illustrative embodiments;

FIG. 2h schematically illustrates a circuit diagram including a plurality of matched transistor elements; and

FIG. 2i schematically illustrates a top view of the transistor elements of FIG. 2h arranged in accordance with illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the principles disclosed herein relate to integrated circuits and methods for forming the same, in which circuit elements comprised of a plurality of unit devices may be appropriately positioned such that a gradient, for example, a technology gradient caused by a systematic variation of one or more manufacturing processes, may be reduced in that a similar effect of the respective technology gradient may be caused in each of the plurality of circuit elements. Typically, technology gradients may have a spatial variation along a direction, which may not be predictable in advance, while, in sophisticated manufacturing technologies, however, the effect of a corresponding systematic variation across a relatively small number of unit devices, which may typically be formed on the basis of the minimum critical dimensions, may be less pronounced. Consequently, according to the principles disclosed herein, the unit devices may be associated to the plurality of circuit elements such that, in some illustrative embodiments, a basic “cell” may be defined, which may be repeated in a regular manner, thereby obtaining a substantially identical spatial relationship of the unit devices for each of the plurality of the circuit elements along at least two different lateral directions. In other illustrative embodiments, an appropriate spatial relationship of the members of one circuit element may be selected such that a similar effect in view of a systematic variation may also be obtained for the members of the other circuit elements that have to be matched, thereby also providing enhanced robustness with respect to technology gradients. Consequently, contrary to conventional layout strategies, the present disclosure provides techniques for reducing systematic mismatches caused by direction-dependent gradients for a plurality of circuit elements, i.e., for three or more circuit elements, such as transistors, capacitors, resistors and the like, wherein each of the circuit elements may in turn be comprised of a plurality of unit devices.

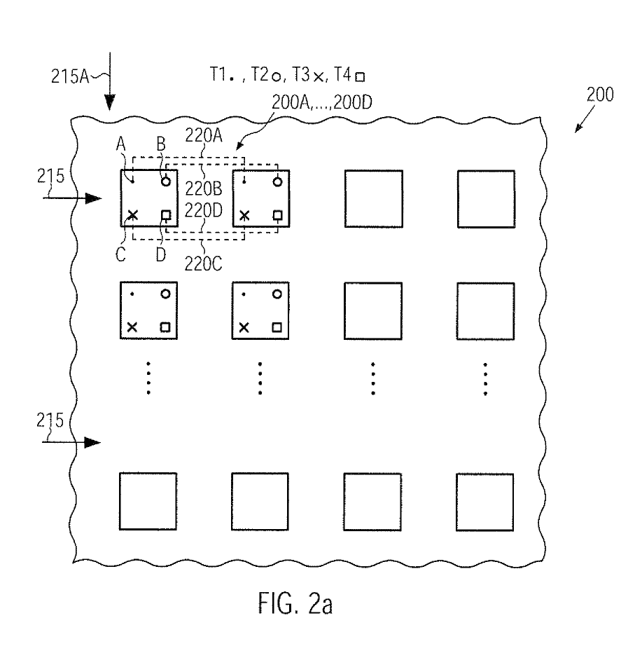

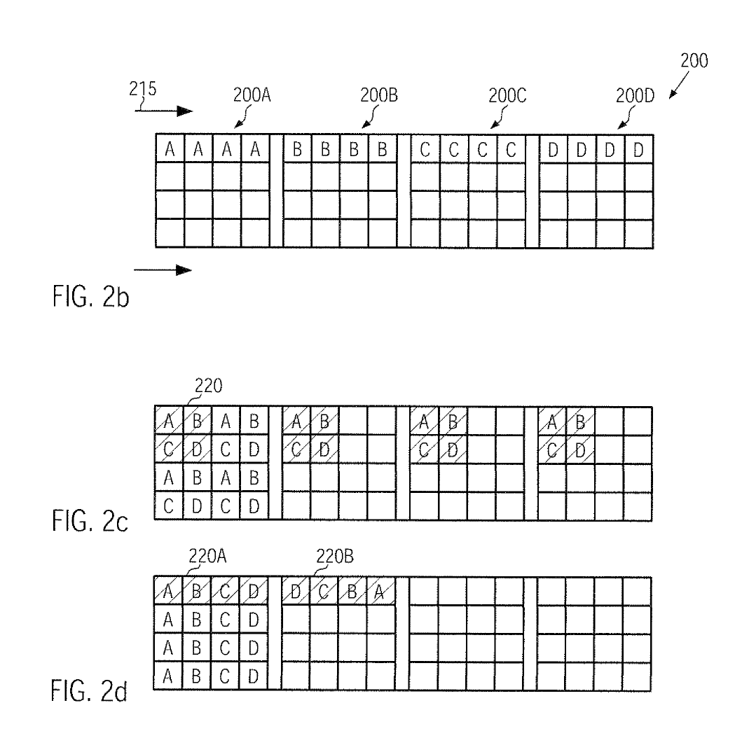

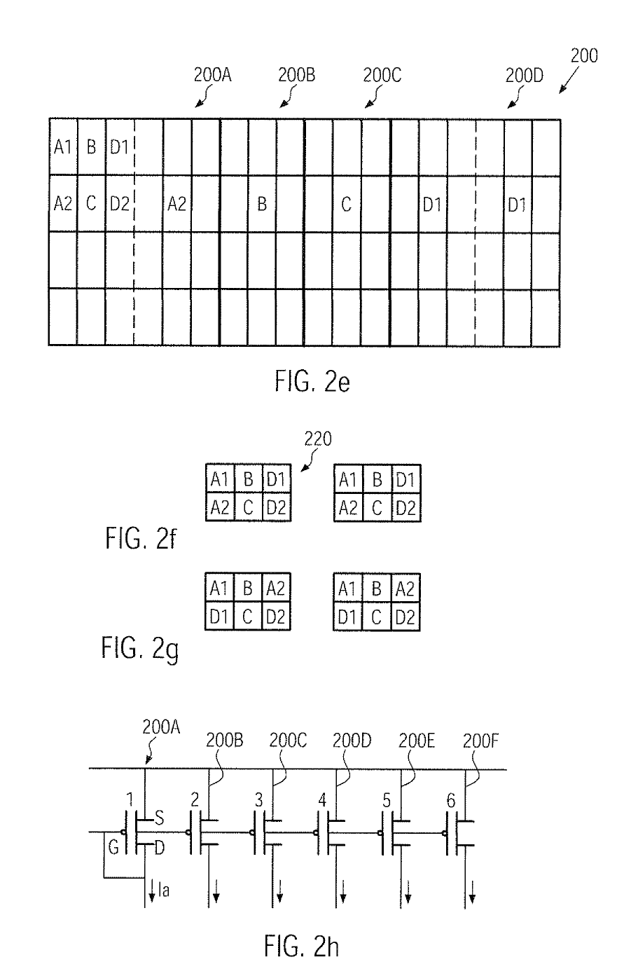

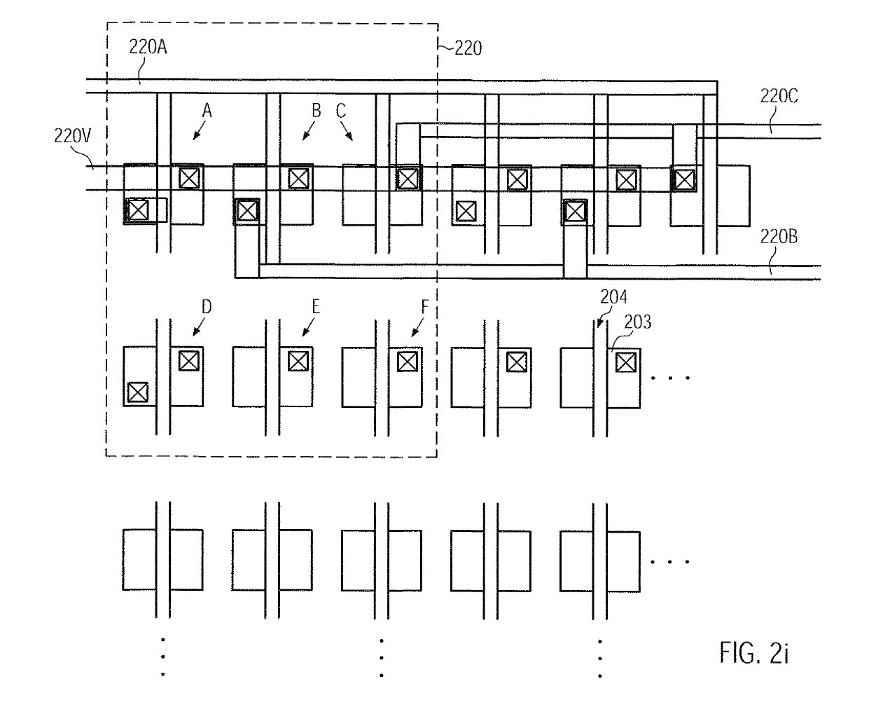

FIG. 2a schematically illustrates a top view of an integrated circuit 200, which may represent any type of integrated circuit including an analog circuit portion, in which a plurality of circuit elements, i.e., three or more circuit elements, an array of circuit elements and the like, have to be matched to each other. That is, the plurality of circuit elements have specified design characteristics, which may, however, vary due to random effects and systematic effects, as previously explained, wherein, however, in view of accuracy, systematic effects should influence the circuit elements in substantially the same manner, thereby enabling an efficient compensation for these systematic effects. For example, the integrated circuit 200 may comprise a plurality of unit devices A, B, C, D which may represent transistor elements, capacitive structures, resistive structures, which may be formed on the basis of minimum critical dimensions in accordance with the technology standard under consideration. In some illustrative embodiments, the different types of unit devices A, B, C, D may represent two or more different structures when enhanced “matching” of different types of circuit elements may be desired. In other illustrative embodiments, the unit devices A, B, C, D may represent basically the same device structures formed on the basis of identical design criteria. That is, the unit devices A, B, C, D may represent identical transistor elements, capacitors, resistors and the like, wherein, as previously indicated, respective variations may have been introduced during the process of forming the unit devices A, B, C, D. In the embodiment shown, the unit devices A, B, C, D may be used for defining a plurality of circuit elements 200A, 200B, 200C, 200D, which may thus represent circuit elements having a desired overall size as determined by the number of unit devices used for actually forming the respective circuit elements 200A, 200B, 200C, 200D. Hence, it may be assumed that the portion shown in FIG. 2a may represent the four circuit elements 200A, 200B, 200C, 200D which may be “distributed” across the illustrated area on the basis of the unit devices A, B, C, D such that the effect of a systematic variation may be similar for each of the circuit elements 200A, 200B, 200C, 200D. In the embodiment shown, a respective spatial arrangement of the unit devices A, B, C, D may be accomplished in such a manner that the spatial relationship of the unit devices A of the circuit element 200A may be substantially the same as the spatial relationship of the unit devices B forming the circuit element 200B and also for the unit devices C and D defining the circuit elements 200C, 200D. In the embodiment shown, the substantially identical spatial relationship may be obtained for at least two dependent lateral directions, i.e., directions parallel to a surface of the integrated circuit 200, as defined by a semiconductor layer in and above which typically the unit devices A, B, C, D are formed, as, for instance, also explained with reference to the transistor element 100. For example, in FIG. 2a, a basic “cell” 220 may be defined, which may comprise unit devices belonging to each of the circuit elements 200A, 200B, 200C, 200D, as indicated by A, B, C, D. It should be appreciated that, as previously indicated, the unit devices A, B, C, D of the basic cell 220 may have substantially the same structure, wherein grouping to form the respective circuit elements 200A, 200B, 200C, 200D may be accomplished on the basis of an appropriate interconnect structure, which may appropriately connect the unit devices belonging to the circuit element 200A, as indicated by the dashed line 220A. Similarly, each of the unit devices for the element 200B may be connected, as indicated by the line 220B, each of the unit devices for the element 200C may be connected as indicated by the line 220C and finally each unit device D may be connected as indicated by the line 220D. Hence, the entirety of unit devices A connected by the interconnect structure 220A may define the circuit element 200A. Similarly, the unit devices B, C, D and the respective interconnect structures 220B, 220C and 220D may define the circuit elements 200B, 200C and 200D, respectively. As previously indicated, a technology variation, as may typically be encountered during the fabrication of sophisticated semiconductor devices, may be less pronounced within a single basic cell 220 due to the reduced dimensions and the close proximity of the respective unit devices within a single basic cell 220. On the other hand, a technology gradient 215 may result in a significant variation along a specified spatial direction, which however may “attack” the circuit elements 200A, 200B, 200C, 200D in a very similar manner due to the spatial configuration of the unit devices A, B, C, D. For example, in the embodiment shown, the spatial relationship along a first direction as, for instance, indicated by the gradient 215 between the individual unit devices A may be defined by the position and configuration of the unit devices A within the basis cells 220 and their positioning across the area corresponding to the entirety of circuit elements 200A, 200B, 200C, 200D. These spatial relationships between the unit devices A along the direction 215 are substantially the same as the spatial relationship of the unit devices B to each other along the direction 215. Similarly, substantially the same spatial relationship is obtained for the unit devices C to each other along the direction 215 and the unit devices D along the direction 215. Consequently, a spatially varying characteristic, for instance, a variation of layer thickness, dopant concentration and the like, as indicated by the gradients 215 may therefore have a similar effect on each of the circuit elements 200A, 200B, 200C, 200D. Furthermore, as illustrated, if a gradient 215A corresponding to a different lateral direction may “act” on the circuit elements 200A, 200B, 200C, 200D, in this case also a similar effect may be created in the circuit elements 200A, 200B, 200C, 200D, since also in this direction the unit devices A have the same spatial relationship to each other as the unit devices B, as do the unit devices C and D to each other. Consequently, the effect of the gradient 215A may be reduced on the overall circuit configuration defined by the circuit elements 200A, 200B, 200C, 200D. In the embodiment shown, the same holds true for any lateral direction, thereby providing a high degree of robustness with respect to technology gradients.

It should be appreciated that, in the embodiment illustrated in FIG. 2a, the spatial relationship of the unit devices is such that with respect to a predefined lateral direction, for instance such as the direction 215, a substantially identical distance between two nearest neighbors of the unit devices A may be obtained. Similarly, in another lateral direction, such as the direction 215A, a substantially constant distance between nearest neighbors in this direction may also be obtained, which, however, may not necessarily be the same as the constant distance along another lateral direction, such as the direction 215. In other cases, the distance between adjacent unit devices of the same circuit element in one lateral direction may vary, for instance by reconfiguring the arrangement of the unit devices A, B, C, D within a plurality of cells 220.

FIG. 2b schematically illustrates the integrated circuit comprising the four circuit elements 200A, 200B, 200C, 200D in a non-matched state. That is, the circuit element 200A, comprised of unit devices A, may respond significantly differently to a technology gradient 215, at least for some lateral directions, compared to the circuit element 200D comprised of the unit devices D. For the intermediate devices 200B, 200C with respect to the direction 215, a less pronounced difference may be created which, however, may result in a significant deviation of the overall circuit performance if a high degree of matching of all four circuit elements 200A, 200B, 200C, 200D may be required.

FIG. 2c schematically illustrates the circuit elements 200A, 200B, 200C, 200D when the unit devices A, B, C, D may be positioned in accordance with a spatial arrangement, as previously described with reference to FIG. 2a. That is, in the embodiment shown, a basic cell 220 may be defined on the basis of unit devices A, B, C, D, thereby distributing the circuit elements 200A, 200B, 200C, 200D, which may result in a similar response to a technology gradient, irrespective of its orientation.

FIG. 2d schematically illustrates the integrated circuit 200 in accordance with a further embodiment with a basic cell 220A in the form of a row of unit devices, which may be repeated in an appropriate manner so as to obtain the desired spatial relationship for each type of unit devices according to a specified lateral direction. As shown, different basic cells may be defined by changing the order of the unit devices therein, while also different types of basic cells may be used simultaneously in order to compensate for significant change of a specific characteristic along one direction. That is, as shown in FIG. 2d, when a significant variation of the characteristic under consideration, such as an oxide thickness and the like, may occur across the basic cell 220A, the order of the unit devices may be reversed in the cell 220B, thereby providing a certain degree of averaging the effect of the gradient 215 across the basic cells 220A, 220B. However, also in this case, the spatial relationship of each type of unit devices to each other along a first direction may be the same and also the spatial relationships of the unit devices of one type along a different lateral direction may be identical, but may be different from the spatial relationship of the previous direction, as previously explained. Consequently, also in this case, a very similar response of each of the circuit elements 200A, 200B, 200C, 200D with respect to a gradient acting along any direction may be achieved.

FIG. 2e schematically illustrates the integrated circuit 200 according to a further illustrative embodiment in which the circuit elements 200A, 200B, 200C, 200D may be comprised of the unit devices A, B, C, D having the same configuration, wherein, however, a different number of unit devices may be used to obtain a desired ratio of the sizes of the circuit elements 200A, 200B, 200C, 200D. In the embodiment shown, it may be assumed that the devices 200A, 200D may have twice the dimension compared to the circuit elements 200B, 200C. For example, when representing a transistor element, the drive current capability of the circuit elements 200A, 200D may be twice that of the transistors 200B, 200C. In other cases, for capacitive structures, the capacitance of the circuit elements 200A, 200D may be twice the capacitance of the capacitors 200B, 200C. Also in this case, the unit devices may be appropriately distributed in accordance with their mutual spatial relationship, as previously explained, in order to provide a similar effect on each of the circuit elements 200A, 200B, 200C, 200D with respect to a gradient acting along a lateral direction. That is, the unit devices may be connected with each other so as to obtain a spatial relationship for each type of unit device that is the same along one or more lateral directions, as previously explained.

FIG. 2f schematically illustrates a basic cell 220, which may be used for appropriately associating the unit devices A, B, C, D to the circuit elements 200A, 200B, 200C, 200D. For example, it may be assumed that unit devices A forming the circuit element 200A may be divided into unit devices A1 and A2 so that cell 220 may comprise twice as many unit devices compared to the circuit element 200B, 200C. Similarly, the basic cell 220 may comprise two unit devices D1, D2 each corresponding to the circuit element 200D. Thus, the basic cells 220 may be defined by the array of FIG. 2e, thereby establishing, along a lateral direction, the same spatial relationship for each type of unit devices, wherein the unit devices A1, A2 are considered as “different” devices of unit devices and similarly the devices D1 and D2 are considered as “different” types of unit devices.

FIG. 2g schematically illustrates the basic cell 220 according to a different configuration wherein it should be appreciated that any desired configuration of the unit devices A1, A2, B, C, D1 and D2 may be used within a basic cell 220 in order to obtain a similar response of the circuit elements 200A, 200D with respect to a gradient according to an arbitrary lateral direction.

FIG. 2h schematically illustrates a circuit diagram in which a plurality of circuit elements 200A, 200B, 200C, 200D, 200E, 200F, for instance in the form of transistor elements, may be provided as matched devices, wherein the transistors 200A, 200B, 200C, 200D, 200E, 200F may act as current sources, the current of which may be defined by, for instance, the first transistor 200A.

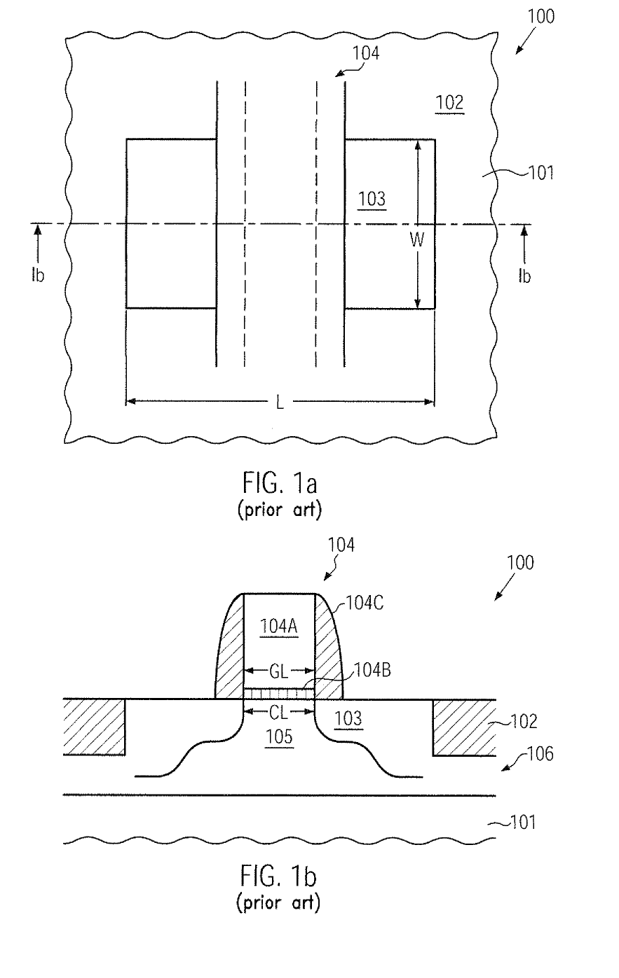

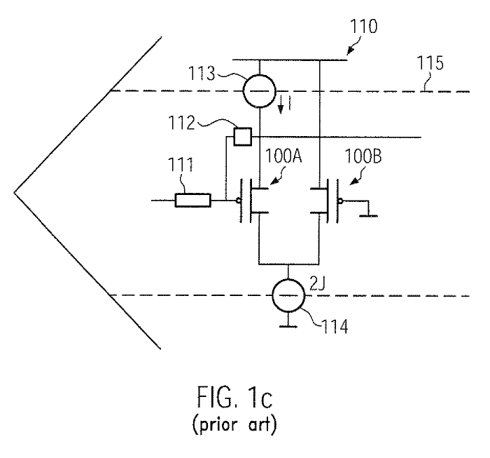

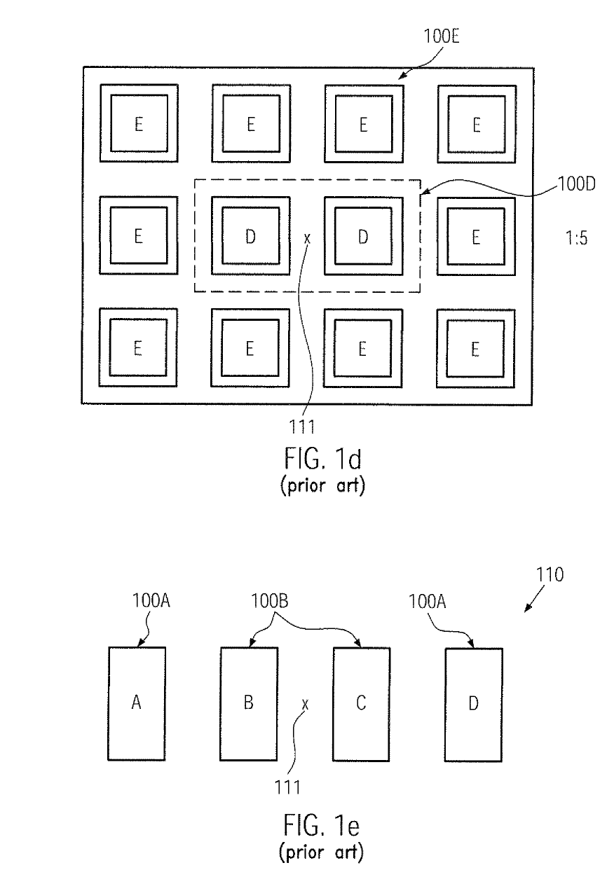

FIG. 2i schematically illustrates the integrated circuit 200 comprising a circuit portion corresponding to the transistors 200A, 200B, 200C, 200D, 200E, 200F, as shown in FIG. 2h. As illustrated, an array of unit devices A, B, C, D, E, F may be provided, which may have the same configuration which may be similar to the configuration as described with reference to FIGS. 1a and 1b. That is, the unit devices may represent transistor elements formed on the basis of design criteria corresponding to the technology standard under consideration. That is, each of the unit devices A, B, C, D, E, F may comprise drain and source regions 203 and a gate electrode structure 204, as previously explained. As illustrated, six unit devices A, B, C, D, E, F may be provided in close proximity to each other within the corresponding array, thereby defining the basic cell 220 so that, for instance, the unit device A may correspond to the transistor 200A. In FIG. 2h, unit device B may correspond to the transistor 200B, and so on. Furthermore, the integrated circuit 200 may comprise an interconnect structure, for instance comprising a portion 220A which may connect the gate electrode structures of all unit devices A, B, C, D, E, F as may be seen from the circuit diagram in FIG. 2h. Similarly, the drain areas 203 of all unit devices A may connect to their gate electrode structures by any appropriate interconnect system. Moreover, an interconnect portion 220V may connect all source terminals 203 of the transistors 200A, 200B, 200C, 200D, 200E, 200F, as is also shown in the circuit diagram of FIG. 2h. Additionally, an interconnect structure 220B may connect respective unit devices of “type B” and respective interconnect structures 220C, 220D, 200E, 220F may connect the unit devices of the corresponding type. Hence, the unit devices of the same type in combination with the corresponding interconnect structure may thus define the circuit elements 200A, 200B, 200C, 200D, 200E, 200F.

Consequently, a high degree of robustness with respect to technology gradients may be accomplished since each of the transistors 200A, 200B, 200C, 200D, 200E, 200F may respond in a similar manner to the gradient due to the special spatial assignment of unit devices to the respective circuit elements.

The integrated circuit 200 as shown in FIG. 2i may be formed on the basis of well-established process techniques, as also previously described with reference to the transistor 100, wherein, however, contrary to conventional strategies, after defining and designing the unit devices A, B, C, D, E, F which may have substantially the same configuration, an appropriate assignment of unit devices to the circuit elements may be performed and the respective interconnect structures 220A, 220B, 220C, 220D, 220E, 220F may be designed so as to obtain the desired assignment in terms of an electric connection. Hence, after forming the basic transistor structures, an appropriate contact structure, in combination with a respective metallization system, may be provided so as to obtain the desired assignment of the unit devices A, B, C, D, E, F to the transistors 200A, 200B, 200C, 200D, 200E, 200F.

As a result, the present disclosure provides enhanced robustness with respect to systematic transistor mismatch in sophisticated analog circuit portions, when a plurality of circuit elements, that is, three or more circuit elements, are to be matched in order to obtain enhanced overall circuit performance. For this purpose, the spatial arrangement of the unit devices may be selected such that a spatial relationship of unit devices corresponding to a specific one of the circuit elements may be substantially the same for each of the circuit elements along a specific lateral direction so that a response of the individual circuit elements with respect to a technology gradient in this direction may be very similar. For example, an arrangement may be selected in which the distance relation between neighboring unit devices of the same cell may be the same for each type of unit devices along a specified direction and a non-invariant spatial relationship of the respective unit devices of different circuit elements may also be obtained in any lateral direction, thereby ensuring a very similar response to a technology gradient.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. An integrated circuit, comprising:
three or more circuit elements, each of which is comprised of a plurality of substantially identical unit devices, each unit device belonging to a respective one of said three or more circuit elements having, with respect to a first direction, a first substantially constant distance to a nearest neighboring one of said unit devices belonging to said respective one of the three or more circuit elements, and each unit device belonging to said respective one of said three or more circuit elements having, with respect to a second direction, a second substantially constant distance to a nearest neighboring one of said unit devices belonging to said respective one of the three or more circuit elements.

2. The integrated circuit of claim 1, wherein said three or more circuit elements represent circuit elements of an analog circuitry comprised in said integrated circuit.

3. The integrated circuit of claim 2, wherein said three or more circuit elements represent transistors.

4. The integrated circuit of claim 3, wherein said substantially identical unit devices have a gate length of 50 nm or less.

5. The integrated circuit of claim 1, wherein said three or more circuit elements represent capacitors.

6. The integrated circuit of claim 1, further comprising three or more second circuit elements differing from said three or more circuit elements in at least one structural feature, each of said three or more second circuit elements is comprised of a plurality of substantially identical second unit devices, wherein each second unit device belonging to a respective one of said three or more second circuit elements has, with respect to said first direction, a third substantially constant distance to a nearest neighboring one of said second unit devices belonging to said respective one of the three or more second circuit elements, and each second unit device belonging to said respective one of said three or more second circuit elements has, with respect to said second direction, a fourth substantially constant distance to a nearest neighboring one of said second unit devices belonging to said respective one of the three or more second circuit elements.

7. The integrated circuit of claim 6, wherein said unit devices and said second unit devices represent transistor elements of different configuration.

8. The integrated circuit of claim 6, wherein said unit devices represent transistor elements and said second unit devices represent at least one of capacitive and resistive elements.

9. The integrated circuit of claim 6, wherein said unit devices represent transistor elements of a first conductivity type and said second unit devices represent transistor elements of a second conductivity type that is complementary to said first conductivity type.

10. The integrated circuit of claim 1, wherein each unit device belonging to a respective one of said three or more circuit elements has, with respect to any lateral direction, a substantially constant distance associated to said any lateral direction to a nearest neighboring one of said unit devices belonging to said respective one of the three or more circuit elements.

11. An integrated circuit, comprising:
an analog circuit portion; and
a plurality of more than two circuit elements provided in said analog circuit portion, each of said plurality of circuit elements being comprised of a plurality of unit devices of substantially the same configuration, wherein, for each of the plurality of circuit elements, a spatial relationship of unit devices along a lateral direction is substantially identical.

12. The integrated circuit of claim 11, further comprising a plurality of second circuit elements, each of which is formed in said analog circuit portion and comprised of a plurality of second unit devices that differ in at least one structural feature from said unit devices.

13. The integrated circuit of claim 12, wherein a spatial relationship of second unit devices along a lateral direction is substantially identical for each of said plurality of second circuit elements.

14. The integrated circuit of claim 11, wherein a second spatial relationship of said unit devices is substantially identical for each of said circuit elements along a second lateral direction.

15. The integrated circuit of claim 14, wherein said spatial relationship and said second spatial relationship differ from each other.

16. The integrated circuit of claim 11, wherein said spatial relationship represents a substantially constant spacing between said unit devices of a respective one of said plurality of circuit elements.

17. The integrated circuit of claim 11, wherein said unit devices represent at least one of transistor elements, capacitive elements and resistive elements.

18. The integrated circuit of claim 17, wherein said unit devices represent transistor elements having a gate length of approximately 50 nm or less.

19. A method, comprising:
defining a plurality of unit devices, said unit devices having the same design and defining a plurality of circuit elements of an integrated circuit;
assigning the plurality of unit devices to said plurality of circuit elements so as to obtain the same spatial relationship of unit devices along an arbitrary lateral direction for each of the plurality of circuit elements; and
forming said plurality of circuit elements above a substrate using said assignment.

20. The method of claim 19, further comprising positioning each of the unit devices defining a respective one of said plurality of circuit elements with a constant spacing along said arbitrary direction.
